(19) United States
(12) Patent Application Publication
(10) Pub. No.: US 2005/0179035 A1
(43) Pub. Date: Aug. 18, 2005

(54) Apparatus and method to access a plurality of pn-junctions with a limited number of pins

(76) Inventors: Paul F. Illegems, Tucson, AZ (US); Klaas Wortel, Phoenix, AZ (US)

Correspondence Address: Jeffrey C. Hood;Meyertons, Hood, Kivlin, Kowert & Goetzel PC, P.O. Box 398, Austin, TX, 78767, US

(21) Appl. No.: 10/781,026

(22) Filed: Feb. 18, 2004

(51) Int. Cl. H01L 23/58; G01R 31/26

(52) U.S. Cl. 257/48; 438/14; 438/18

(57) ABSTRACT

In one embodiment, a plurality of pn-junctions are grouped into n(n-1)/2 pairs (where n is an integer greater than 1) and each pn-junction pair includes a first pn-junction coupled antiparallel to a second pn-junction. In addition, n access points are coupled to the plurality of pn-junctions, and through the n access points n-1 pn-junctions are simultaneously accessible. In another embodiment, an integrated circuit is coupled to the plurality of pn-junctions via the n access points. In one embodiment, the integrated circuit may be configured as a temperature measurement IC and the plurality of pn-junctions may be used as temperature sensors. In this embodiment, the temperature measurement IC may be configured to access the first pn-junction independently from the second pn-junction and may be configured to access n-1 pn-junctions simultaneously to perform temperature measurements.

### BACKGROUND OF THE INVENTION

1. Field of the Invention

This invention relates to electronic circuits and, more particularly, to circuits for accessing a plurality of pn-juctions with a limited number of pins.

2. Description of the Related Art

As computer systems and other electronics become more complex, more compact, and run faster, it is critical to monitor temperatures associated with particular devices within the computer systems. Traditional temperature sensing techniques, such as thermocouples and thermistors, are now being displaced by semiconductor temperature sensors due to their ease of integration and use.

Diodes are often used as temperature sensors due to a substantially linear relationship (≈2.2 mV/° C.) between the voltage across a pn-junction and the temperature of the junction. Therefore, by providing a constant current and measuring the forward-biased voltage across the pn-junction, the temperature associated with a particular device having the pn-junction may be determined from the temperature-voltage relationship. Diodes are one of the cheapest temperature sensors available. However, one disadvantage of using diodes as temperature sensors may be that the initial forward-biased voltage of diodes varies with process and device features; therefore, diodes may have to be individually calibrated to avoid introducing an error into the temperature measurement. Individual device calibration may be possible but it may not practical.

Transistors (e.g., bipolar junction transistor or BJT) are also regularly used as temperature sensors to determine the temperature associated with a particular device. If two different current are provided to a respective transistor, the difference in base-emitter voltage (ΔV_{BE}=V_{BE1}−V_{BE2}) at the two different currents is proportional to the absolute temperature of the transistor. Since ΔV_{BE} is a difference or change in base-emitter voltage and not a measured voltage, ΔV_{BE} is independent of the pn-junction's forward-biased voltage or other differences due to manufacturing variations. Therefore, temperature measurements obtained by calculating ΔV_{BE} are usually more accurate than temperature measurements obtained by measuring the forward-biased voltage of a pn-junction and using the junction voltage-temperature relationship (≈2.2 mV/° C.).

The relationship between temperature and ΔV_{BE} of a transistor may be given by:
T=q*(V_{BE1}−V_{BE2})/(k*ln(I₁/I₂))
where k≈1.38×10⁻²³, Boltzmann's constant
T=absolute temperature in Kelvin
q≈1.602×10⁻¹⁹, charge of an electron
I₁=first current level forced through the pn-junction
I₂=second current level forced through the pn-junction
V_{BE1}=resulting base-emitter voltage across the pn-junction due to I₁
V_{BE2}=resulting base-emitter voltage across the pn-junction due to I₂
V_{BE1}−V_{BE2}=ΔV_{BE}=difference in base-emitter voltage due to I₁ and I₂

Using the equation shown above, the difference in base-emitter voltage at a pn-junction of the transistor may be measured to determine the temperature associated with the pn-junction. Therefore, a diode or a transistor that is being used as a temperature sensor may be useful for determining the temperature of the particular device or integrated circuit (IC) where the temperature sensor is located. It is possible to approximate the temperature of circuits near the location of the temperature sensors but the temperature measurements may not be accurate. Ideally, the temperature sensors should be located within the circuit needing the temperature monitoring. Therefore, the circuit having the temperature sensors may need to dedicate a plurality of pins specifically for the temperature sensors.

An IC may have 2 dedicated pins to measure the base-emitter voltage across the pn-junction of the transistor that is being used as a temperature sensor, for example, one pin to receive the current and the other to serve as the return. In this case, an IC having 2 temperature sensors may have 4 pins dedicated for temperature sensing, an IC having 3 temperature sensors may have 6 dedicated pins, and so on. This technique for incorporating temperature sensors into ICs may not be practical because the temperature sensors may use too many pins. One method to overcome this problem is to connect 2 diodes to 3 pins. For example, 2 diodes could be connected to 2 pins and use the ground pin (the 3^{rd} pin) as a common return. However, using the ground pin as a return pin may lead to inaccurate voltage measurements because it may involve sampling the V_{BE} voltages relative to a noisy ground.

### SUMMARY OF THE INVENTION

Various embodiments of circuits for accessing a plurality of pn-juctions with a limited number of pins are disclosed. In one embodiment, a plurality of pn-junctions are grouped into n(n-1)/2 pairs (where n is an integer greater than 1) and each pn-junction pair includes a first pn-junction coupled antiparallel to a second pn-junction. In addition, n access points are coupled to the plurality of pn-junctions, and through the n access points n-1 pn-junctions are simultaneously accessible.

In one embodiment, a method for arranging the plurality of pn-junctions comprises grouping n(n-1) pn-junctions into n(n-1)/2 pairs and coupling the n(n-1) pn-junctions to n access points. In this embodiment, each pn-junction pair comprises a first pn-junction coupled antiparallel to a second pn-junction.

In another embodiment, a system comprises a plurality of pn-junctions grouped into n(n-1)/2 pairs, where each pn-junction pair includes a first pn-junction coupled antiparallel to a second pn-junction, and an integrated circuit coupled to the plurality of pn-junctions via n access points. In this embodiment, the integrated circuit is configured to access the first pn-junction and the second pn-junction independently. Furthermore, the integrated circuit is configured to access n-1 pn-junctions simultaneously via the n access points.

In one embodiment, the integrated circuit may be configured as a temperature measurement IC and the plurality of pn-junctions may be used as temperature sensors. In this embodiment, the temperature measurement IC may be coupled via n access points or n pins to an arrangements of the pn-junctions having n(n-1)/2 pairs. Each pair of pn-junctions includes a first pn-junction coupled antiparallel to a second pn-junction. The temperature measurement IC may be further configured to access the n(n-1) pn-junctions to perform temperature measurements. In this embodiment, the temperature measurement IC may be configured to access the first pn-junction independently from the second pn-junction to determine the temperature associated with each of the pn-junctions. Also, the temperature measurement IC may be configured to access n-1 pn-junctions simultaneously via the n access points to determine the temperature associated with the n-1 pn-junctions simultaneously.

### BRIEF DESCRIPTION OF THE DRAWINGS

FIG. 1 illustrates several arrangements of pn-junctions that are grouped into pairs.

FIG. 2 is a circuit diagram of one embodiment of a temperature measurement IC coupled to a pn-junction arrangement.

FIG. 3 is a circuit diagram of another embodiment of a temperature measurement IC coupled to another pn-junction arrangement.

FIG. 4 is a circuit diagram illustrating a possible path of current Iₒ₁ within the circuit of FIG. 3 to determine the temperature associated with a pn-junction.

FIG. 5 is a simplified drawing illustrating one embodiment of a circuit including a five-pin arrangement of pn-junctions.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

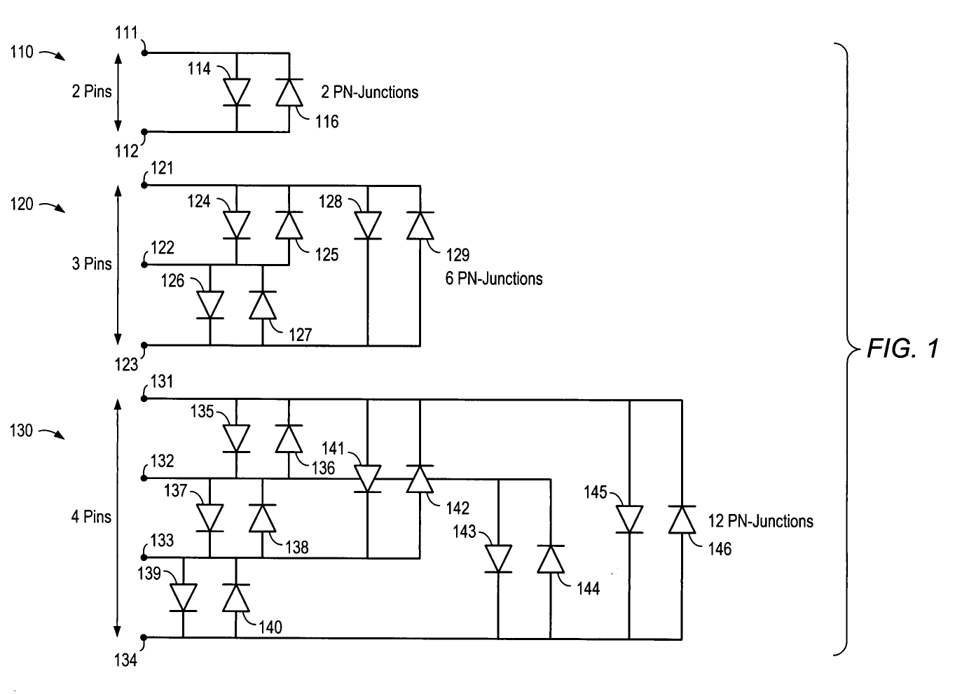

FIG. 1 illustrates several arrangements of pn-junctions that are grouped into pairs. The illustrated arrangements allow the plurality of pn-junctions to be accessed via a limited number of pins. Specifically, a plurality of pn-junctions may be grouped into n(n-1)/2 pairs to be accessed via n pins or n access points, where n is an integer greater than 1. Each pair of pn-junctions includes a first pn-junction coupled antiparallel to a second pn-junction. In one embodiment, the plurality of pn-junctions are represented by a plurality of diodes, which may be used as temperature sensors. It is noted however that other pn-junction devices may be used as temperature sensors, for example, a plurality of transistors.

As illustrated in FIG. 1, in one embodiment, arrangement 110 includes 2 pn-junctions that may be accessed through 2 pins. In arrangement 110, pn-junctions 114 and 116 are coupled to pins 111 and 112. In another embodiment, arrangement 120 includes 6 pn-junctions, which are grouped into 3 pairs and may be accessed through 3 pins. In arrangement 120, pn-junctions 124 and 125 are coupled to pins 121 and 122, pn-junctions 126 and 127 are coupled to pins 122 and 123, and pn-junctions 128 and 129 are coupled to pins 121 and 123. In yet another embodiment, arrangement 130 includes 12 pn-junctions, which are grouped into 6 pairs and may be accessed through 4 pins. In arrangement 130, pn-junctions 135 and 136 are coupled to pins 131 and 132, pn-junctions 137 and 138 are coupled to pins 132 and 133, pn-junctions 139 and 140 are coupled to pins 133 and 134, pn-junctions 141 and 142 are coupled to pins 131 and 133, pn-junctions 143 and 144 are coupled to pins 132 and 134, and pn-junctions 145 and 146 are coupled to pins 131 and 134. It is noted however that similar arrangements of pn-junctions may be extended to an embodiment with 5 pins and to additional embodiments with n pins.

In one embodiment, a temperature measurement IC may be coupled to one of the arrangements of pn-junctions having n(n-1)/2 pairs via n pins or n access points. Each pair of pn-junctions includes a first pn-junction coupled antiparallel to a second pn-junction. The temperature measurement IC may access the n(n-1) pn-junctions via the n pins or n access points to determine the temperature associated with each of the pn-junctions. In this embodiment, the first pn-junction may be accessed independently from the second pn-junction. Furthermore, n-1 pn-junctions may be accessed simultaneously.

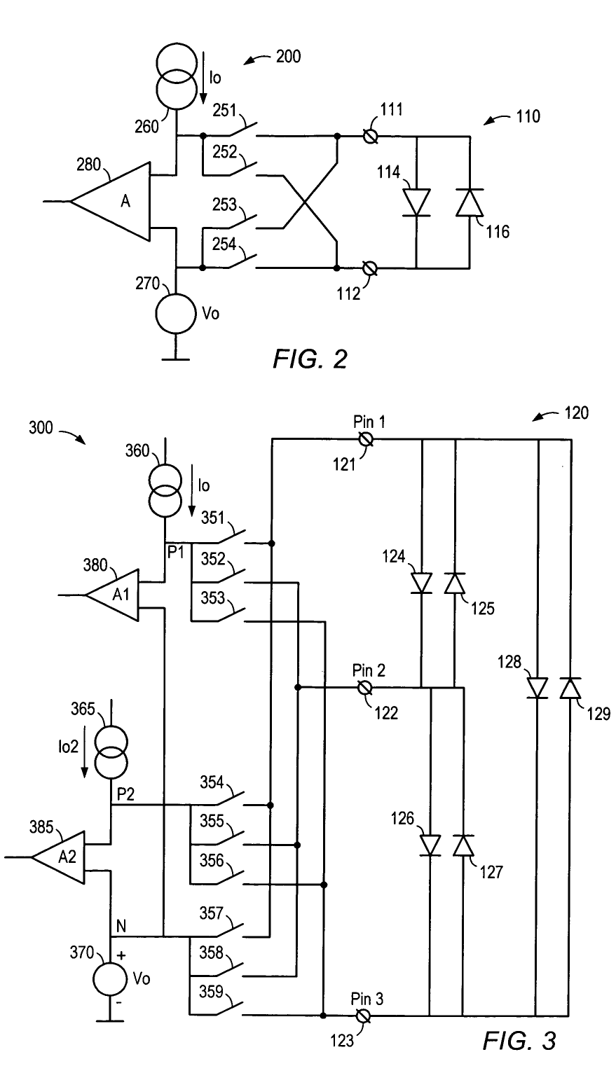

Referring to FIG. 2, a circuit diagram of one embodiment of temperature measurement IC 200 coupled to pn-junction arrangement 110 is shown. Components that correspond to those shown in FIG. 1 are numbered identically for clarity and simplicity. In one embodiment, if a temperature measurement IC is coupled (via n pins) to an arrangement of n(n-1) pn-junctions including n(n-1)/2 pairs of pn-junctions, where n is an integer greater than 1, then the temperature measurement IC includes a plurality of switches and n-1 current sources. Therefore, in the illustrated embodiment of FIG. 2 having 2 pins, temperature measurement IC 200 includes a plurality of switches 251-254 and a current source 260. In addition, temperature measurement IC 200 includes an amplifier circuit 280 and a common mode voltage 270. It is noted however that in other embodiments the number of switches, current sources, and amplifier circuits may vary from the illustrated embodiment.

In the illustrated embodiment, pn-junctions 114 and 116 may be used as temperature sensors. Accordingly, temperature measurement IC 200 may access pn-junctions 114 and 116 of arrangement 110 to determine the temperature associated with each of the pn-junctions. In one embodiment, pn-junctions 114 and 116 may each be included in a respective transistor. In this embodiment, the base and the collector of each of the transistors may be connected together so each of the transistors operates similarly to a diode. In the illustrated embodiment of FIG. 2, if pn-junctions 114 and 116 are each included in a respective transistor and are coupled to the 2 pins in an antiparallel configuration, depending on the direction of the current Iₒ from current source 260, one pn-junction will be forward-biased and conducting and the other pn-junction will be reverse-biased and non-conducting. By varying the direction of the current Iₒ, the voltage V_{BE} of both transistors may be measured independently by using only 2 pins.

In one embodiment, by closing switches 251 and 254 and opening switches 252 and 253, the current Iₒ will be driven in one direction and the V_{BE} of the transistor having pn-junction 114 may be seen across the two pins and measured by temperature measurement IC 200. In this embodiment, pn-junction 116 will be reversed-biased and will not influence the measurements. On the other hand, by closing switches 252 and 253 and opening switches 251 and 254, the direction of the current Iₒ is reversed and V_{BE} of the transistor including pn-junction 116 may be seen across the two pins and measured by temperature measurement IC 200. In one embodiment, temperature measurement IC 200 may include a multiplexer (not shown) to control the switching of the direction of the current Iₒ.

In this embodiment, the temperature associated with the transistor including pn-junction 114 may be determined by providing a first current (I₁) from current source 260 and measuring the first base-emitter voltage (V_{BE1}) at the first current and then providing a second current (I₂) and measuring the second base emitter voltage (V_{BE2}) at the second current. In one embodiment, second current (I₂) may constitute an integer multiple of first current (I₁), for example, I₂ may be 10 times the magnitude of I₁. As described above, V_{BE1} and V_{BE2} of the transistor including pn-junction 114 may be measured by closing switches 251 and 254 and opening switches 252 and 253. The temperature associated with the transistor having pn-junction 114 may be computed using the following relationship:
T=q*(V_{BE1}−V_{BE2})/(k*ln(I₁/I₂))
where k≈1.38×10⁻²³, Boltzmann's constant
T=absolute temperature in Kelvin
q≈1.602×10⁻¹⁹, charge of an electron
I₁=first current level forced through the pn-junction
I₂=second current level forced through the pn-junction
V_{BE1}=resulting base-emitter voltage across the pn-junction due to I₁
V_{BE2}=resulting base-emitter voltage across the pn-junction due to I₂
V_{BE1}−V_{BE2}=ΔV_{BE}=difference in base-emitter voltage due to I₁ and I₂

Similarly, the temperature associated with the transistor including pn-junction 116 may be determined from the same equation by providing I₁ and I₂ to measure V_{BE1} and V_{BE2} of the transistor. In this case, switches 252 and 253 are closed and switches 251 and 254 are opened.

In one embodiment, temperature measurement IC 200 may include circuitry (not shown) to compute the temperature according to the above relationship between temperature and ΔV_{BE}. It is noted that the temperature derived from the above equation is absolute temperature in Kelvins, which may be readily converted into any desired unit of temperature.

Referring to FIG. 3, a circuit diagram of one embodiment of temperature measurement IC 300 coupled to pn-junction arrangement 120 is shown. Components that correspond to those shown in FIG. 1 are numbered identically for clarity and simplicity. The relationship between number of pins (n) and number of pn-junctions that was described in FIG. 2 also applies to FIG. 3. Therefore, in the illustrated embodiment, temperature measurement IC 300 is coupled (via 3 pins) to an arrangement of 6 pn-junctions (i.e., pn-junctions 124-129) grouped into 3 pairs of pn-junctions. Furthermore, temperature measurement IC 300 includes a plurality of switches 351-359, two current sources 360 and 365 (i.e., n-1 current sources), two amplifier circuits 380 and 385, and a common mode voltage 370.

In one embodiment, a temperature measurement IC may access the first pn-junction of a pair of pn-junctions independently from the second pn-junction. For example, in the illustrated embodiment, temperature measurement IC 300 may access pn-junction 126 independently from pn-junction 127 and may access pn-junction 128 independently from pn-junction 129. Furthermore, in one embodiment, a temperature measurement IC may access n-1 pn-junctions simultaneously as long as the n-1 current sources of the temperature measurement IC have a common return pin (a negative pin). For example, in the illustrated embodiment having 3 pins (i.e., pins 121-123), temperature measurement IC 300 may access 2 pn-junctions simultaneously as long as the 2 current sources (i.e. current sources 360 and 365) have a common return pin.

In one embodiment, temperature measurement IC 300 may access 2 pn-junctions simultaneously to determine the temperature associated with each of the 2 pn-junctions simultaneously. For example, in the illustrated embodiment, to access pn-junctions 126 and 128 simultaneously, switches 351, 355, and 359 are closed and switches 352-354 and 356-358 are opened. By closing switches 351 and 355, current Iₒ₁ will be driven via pin 121 (positive pin) to pn-junction 128 and current Iₒ₂ will be driven via pin 122 (positive pin) to pn-junction 126. By closing switch 359, pin 123 (negative pin) will be the common return pin for current sources 360 and 365.

In the above example, the temperatures associated with pn-junction 126 and pn-junction 128 may be determined simultaneously by providing a first current from current source 360 and current source 365 to pn-junction 126 and pn-junction 128, respectively, and measuring the first base-emitter voltage (V_{BE1}) at the first current of both pn-junction 126 and pn-junction 128. Then, providing a second current from current source 360 and current source 365 to pn-junction 126 and pn-junction 128, respectively, and measuring the second base emitter voltage (V_{BE2}) at the second current of both pn-junction 126 and pn-junction 128. Accordingly, by calculating the difference in base-emitter voltage (ΔV_{BE}) due to I₁ and I₂, the temperature associated with each of pn-junctions 126 and 128 may be determined from the relationship between ΔV_{BE} and temperature described above.

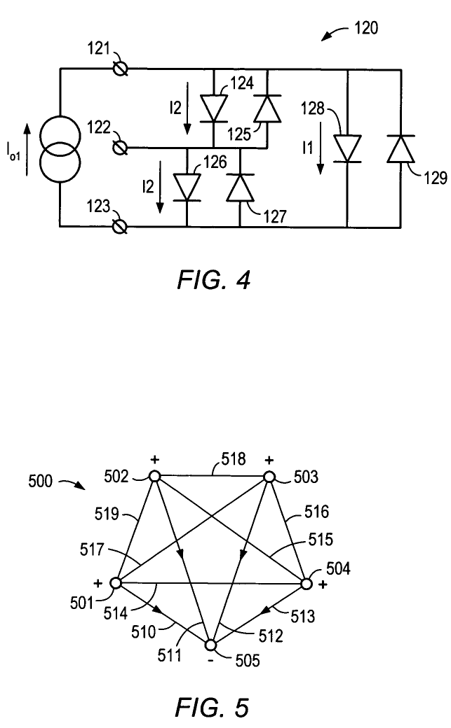

Turning now to FIG. 4, a circuit diagram illustrating a possible path of current Iₒ₁ within the circuit of FIG. 3 to determine the temperature associated with pn-junction 128 is shown. Referring collectively to FIG. 3 and FIG. 4, temperature measurement IC 300 provides current Iₒ₁ and closes switches 351 and 359, which results in the current path illustrated in FIG. 4, to measure the forward-biased voltage (e.g., V_{BE1}) across pn-junction 128. In this embodiment, pn-junctions 124 and 126 are also forward-biased; however, due to the exponential relationship between current and voltage for a pn-junction, the shunt current 12 through pn-junctions 124 and 126 is negligible compared to the current I₁.

Furthermore, in one embodiment, if temperature measurement IC 300 measures the difference in base-emitter voltage (ΔV_{BE}) of a transistor having pn-junction 128, any error that may be introduced into the measurements of base-emitter voltages will be included in both the measurements of V_{BE1} and V_{BE2}. Therefore, ΔV_{BE} may not be significantly affected by the error and the calculated temperature may be an accurate measurement of the temperature associated with pn-junction 128.

Referring to FIG. 5, a simplified drawing illustrating one embodiment of a circuit including a five-pin arrangement of pn-junctions is shown. The illustration includes pins 501-505 and lines 510-519. In the illustrated embodiment, each line between any two pins represents a combination or a pair of two antiparallel pn-junctions. In addition, the pins marked “+” (the positive pins) are the pins connected to a current source and the pin marked “−” (the negative pin) is the common return pin. Furthermore, since this is an arrangement of 20 pn-junctions including 5 pins, 4 pn-junctions (i.e., n-1 pn-junctions) may be accessed simultaneously. For example, in the illustrated embodiment where pin 505 is the common return, one pn-junction of the pair of pn-junctions in each of lines 510-513 may be accessed simultaneously to perform temperature measurements.

The simplified representation of a circuit having 5 pins and 20 pn-junctions shown in FIG. 5 also illustrates that by changing the pin that is being used as the common return (the negative pin) all 20 pn-junctions may be accessed. For example, by using pin 504 as the common return (rather than pin 505 as illustrated in FIG. 5), the current sources at pins 501-503 and 505 may provide currents to lines 513-516; therefore, 4 different pn-junctions may be accessed simultaneously. It is noted that in the embodiment where pin 505 is the common return, one pn-junction of the pair of pn-junctions in line 513 is accessed, and in the embodiment where pin 504 is the common return, the other pn-junction of the pair of pn-junctions in line 513 is accessed.

In an alternative embodiment, the pn-junctions of FIGS. 1-5 may each be included in a respective diode. A diode may be used as a temperature sensor because the forward-biased voltage across a diode has a temperature coefficient of about 2.2 mV/° C., which is a reasonably linear relationship. Therefore, by providing a constant current and measuring the forward-biased voltage, the temperature associated with a particular device or circuit including the diodes may be determined from this voltage-temperature relationship.

In one embodiment, one or more of the pn-junctions in the arrangements of pn-junctions shown in the circuits of FIGS. 1-5 may be located remotely with respect to the temperature measurement IC. As described above, each of the remote pn-junctions, which may be included within a respective diode or transistor, may be used to determine the temperature associated with one or more remote devices or circuits having the one or more remote pn-junctions. In this embodiment, the remote pn-junctions may be coupled to the temperature measurement IC via any type of system or network interconnect structure. In an alternative embodiment, one or more of the pn-junctions in the arrangements of pn-junctions shown in the circuits of FIGS. 1-5 may be located within the temperature measurement IC. In this alternative embodiment, the one or more pn-junctions located within the temperature measurement IC may be used to determine the temperature associated with the temperature measurement IC.

It is noted that each of the temperature measurement ICs of FIGS. 2-3 may be any type of temperature measurement IC, such as an SMBus temperature sensor IC, which may be coupled to a System Management Bus (SMBus). For example, in one embodiment, an SMBus temperature sensor IC may access a plurality of remote temperature sensors, one or more internal temperature sensors, and may include an SMBus interface.

In an alternative embodiment, the plurality of pn-junctions shown in the circuits of FIGS. 1-5 may be the type of pn-junctions that are used to make light-emitting diodes (LEDs). In this alternative embodiment, the n-pin arrangements of LEDs may include n(n-1) LEDs grouped into n(n-1)/2 pairs. Each pair of LEDs includes a first LED coupled antiparallel to a second LED. These arrangements of LEDs allow the plurality of LEDs to be accessed via a limited number of pins. Furthermore, in this alternative embodiment, similarly to the embodiments of FIGS. 1-5, the first LED may be accessed independently from the second LED, and n-1 LEDs may be accessed simultaneously. The n-pin arrangements of LEDs described above may be used in several applications, such as displays, score boards, and alarm indicators.

Although the embodiments above have been described in considerable detail, numerous variations and modifications will become apparent to those skilled in the art once the above disclosure is fully appreciated. It is intended that the following claims be interpreted to embrace all such variations and modifications.

1. An apparatus comprising:
a plurality of pn-junctions grouped into n(n-1)/2 pairs, wherein each pn-junction pair comprises a first pn-junction coupled antiparallel to a second pn-junction; and
n access points coupled to the plurality of pn-junctions, wherein n is an integer greater than 1;
wherein n-1 pn-junctions are simultaneously accessible via the n access points.

2. The apparatus of claim 1, wherein one or more of the plurality of pn-junctions are configured to perform temperature measurements.

3. The apparatus of claim 1, wherein the first pn-junction and the second pn-junction are configured to be accessed independently.

4. The apparatus of claim 1, wherein each one of the plurality of pn-junctions is comprised in a respective diode.

5. The apparatus of claim 1, wherein each one of the plurality of pn-junctions is comprised in a respective transistor.

6. The apparatus of claim 1, wherein each one of the plurality of pn-junctions is comprised in a respective light-emitting diode.

7. A method for arranging a plurality of pn-junctions, the method comprising:
grouping the plurality of pn-junctions into n(n-1)/2 pairs, wherein each pn-junction pair comprises a first pn-junction coupled antiparallel to a second pn-junction; and
coupling the plurality of pn-junctions to n access points, wherein n is an integer greater than 1.

8. The method of claim 7, further comprising accessing n-1 pn-junctions simultaneously via the n access points.

9. The method of claim 7, further comprising accessing the first pn-junction and the second pn-junction independently.

10. A system comprising:
a plurality of pn-junctions grouped into n(n-1)/2 pairs, wherein each pn-junction pair comprises a first pn-junction coupled antiparallel to a second pn-junction, wherein the plurality of pn-junctions are coupled to n access points, wherein n is an integer greater than 1; and
a circuit coupled to the plurality of pn-junctions, wherein the circuit is configured to access n-1 pn-junctions simultaneously via the n access points.

11. The system of claim 10, wherein the circuit is configured to access one or more of the plurality of pn-junctions to perform temperature measurements.

12. The system of claim 10, wherein the circuit is configured to access the first pn-junction and the second pn-junction independently.

13. The system of claim 10, wherein the circuit is configured as a temperature measurement circuit.

14. The system of claim 10, wherein each one of the plurality of pn-junctions is comprised in a respective diode.

15. The system of claim 10, wherein each one of the plurality of pn-junctions is comprised in a respective transistor.

16. The system of claim 15, wherein the circuit is configured to access the respective transistor to perform temperature measurements, wherein in performing the temperature measurements the circuit is operable to provide a first current and a second current to the respective transistor and to determine a change in base-emitter voltage (ΔV_{BE}) of the respective transistor from a first base-emitter voltage (V_{BE1}) corresponding to the first current and a second base-emitter voltage (V_{BE2}) corresponding to the second current.

17. The system of claim 10, wherein each one of the plurality of pn-junctions is comprised in a respective light-emitting diode.

18. A system comprising:
a plurality of pn-junctions grouped into n(n-1)/2 pairs, wherein each pn-junction pair comprises a first pn-junction coupled antiparallel to a second pn-junction, wherein the plurality of pn-junctions are coupled to n access points, wherein n is an integer greater than 1; and
an integrated circuit coupled to the plurality of pn-junctions via the n access points, wherein the integrated circuit is configured to access the first pn-junction and the second pn-junction independently, and wherein the integrated circuit is configured to access n-1 pn-junctions simultaneously via the n access points.

19. The system of claim 18, wherein the integrated circuit is configured to access one or more of the plurality of pn-junctions to perform temperature measurements.

20. The system of claim 18, wherein the integrated circuit is configured as a temperature measurement integrated circuit.

21. The system of claim 18, wherein each one of the plurality of pn-junctions is comprised in a respective diode.

22. The system of claim 18, wherein each one of the plurality of pn-junctions is comprised in a respective transistor.

23. The system of claim 22, wherein the integrated circuit is configured to access the respective transistor to perform temperature measurements, wherein in performing the temperature measurements the integrated circuit is operable to provide a first current and a second current to the respective transistor and to determine a change in base-emitter voltage (ΔV_{BE}) of the respective transistor from a first base-emitter voltage (V_{BE1}) corresponding to the first current and a second base-emitter voltage (V_{BE2}) corresponding to the second current.

24. The system of claim 18, wherein the n access points correspond to n respective pins of the integrated circuit.

25. The system of claim 19, wherein the plurality of pn-junctions are configured as temperature sensors.

26. The system of claim 18, wherein the integrated circuit comprises one or more internal pn-junctions configured as temperature sensors to determine a temperature associated with the integrated circuit.

27. The system of claim 20, wherein the integrated circuit is coupled to a System Management Bus (SMBus).

28. The system of claim 18, wherein each one of the plurality of pn-junctions is comprised in a respective light-emitting diode.
